(19) United States
(12) Patent Application Publication
(10) Pub. No.: US 2025/0101260 A1
(43) Pub. Date: Mar. 27, 2025

(54) CMP POLISHING SOLUTION, STORAGE SOLUTION, AND POLISHING METHOD

(71) Applicant: Resonac Corporation, Tokyo (JP)

(72) Inventors: Keisuke INOUE, Tokyo (JP); Hiroshi ONO, Tokyo (JP)

(21) Appl. No.: 18/727,866

(22) PCT Filed: Jan. 12, 2022
(86) PCT No.: PCT/JP2022/000662

§ 371 Date: Jul. 10, 2024

(51) Int. Cl. C09G 1/02; H01L 21/321

(52) U.S. Cl. CPC C09G 1/02; H01L 21/3212

(57) ABSTRACT

A CMP polishing solution containing abrasive grains, an iron ion supplying agent, an organic acid, an oxidizing agent, and an aqueous liquid medium, in which the abrasive grains include silica particles having sulfo groups and silica particles not having sulfo groups.

### TECHNICAL FIELD

The present invention relates to a CMP polishing solution, a stock solution, and a polishing method.

### BACKGROUND ART

In recent years, new microfabrication technologies have been developed along with higher integration and performance improvement of semiconductor integrated circuits (hereinafter, referred to as “LSIs”). A chemical mechanical polishing (hereinafter, referred to as “CMP”) method is one of the microfabrication technologies and is a technology frequently utilized in the LSI manufacturing processes, particularly planarization of insulating films, formation of metal plugs, formation of buried wiring, and the like in a multilayer wiring formation process.

As an example, the formation of buried wiring using a CMP method will be described. First, a laminated body that includes a base body (for example, a substrate) having a preliminarily formed unevenness on the surface, and a film containing an insulating material (hereinafter, also referred to as “insulating film”) laminated on the base body, is prepared. Next, a film containing a barrier material (hereinafter, also referred to as “barrier film”) is deposited over the entire surface of the insulating film. In addition, a metal film for wiring is deposited over the entire surface of the barrier film so as to fill recess parts (groove parts). Next, any unnecessary metal film for wiring and the barrier film underneath it other than the recess parts are removed by CMP to form buried wiring. Such a wiring forming method is called a damascene method (see, for example, the following Patent Literature 1).

In recent years, tungsten materials such as tungsten (W) and tungsten alloys have come to be used for wiring metal films. Regarding a wiring forming method according to a damascene method using a film containing a tungsten material (hereinafter, also referred to as “tungsten film”), for example, a method including a first polishing step of polishing most of the tungsten film, and a second polishing step of polishing the tungsten film and the barrier film is generally used, and depending on the situation, a third polishing step (finish polishing step) of polishing the tungsten film, the barrier film, and the insulating film is carried out. Patent Literature 1 discloses a CMP polishing solution that is considered to be usable in the above-described method (particularly, the first polishing step).

### CITATION LIST

### Patent Literature

Patent Literature 1: Japanese Patent No. 3822339

### SUMMARY OF INVENTION

### Technical Problem

Usually, in order to suppress the cost associated with transportation, storage, and the like, CMP polishing solutions are often produced in the state of being a stock solution in which abrasive grains and various additive components in the CMP polishing solution are concentrated (for example, concentration is increased to two or more times the original concentration). However, in the state of being a stock solution, the abrasive grains are likely to agglomerate and settle, and the particle size of the abrasive grains in a CMP polishing solution obtained by diluting a stock solution with an aqueous liquid medium tends to increase. When the abrasive grains in the CMP polishing solution become larger, the polishing rate in the polishing process is likely to fluctuate. For that reason, it is desirable that the abrasive grains do not settle in the stock solution over a long period of time and are in a satisfactory dispersed state, that is, the stock solution has a long shelf life.

Patent Literature 1 discloses a polishing solution containing silica or alumina, ferric nitrate, and an oxidizing agent (hydrogen peroxide or the like). However, in this Patent Literature 1, the shelf life is not disclosed. Generally, in stock solutions having the composition disclosed in Patent Literature 1 as described above, settling of the abrasive grains easily occurs, and therefore, the shelf life is shortened. For this reason, there is still a demand for a CMP polishing solution having a long shelf life in the state of being a stock solution and having a high polishing rate for a tungsten material.

An object of the present invention is to provide a CMP polishing solution that is likely to have a long shelf life in the state of being a stock solution and has a high polishing rate for a tungsten material, a stock solution from which the CMP polishing solution is obtained, and a polishing method using the CMP polishing solution or using a polishing solution obtained from the stock solution.

### Solution to Problem

An aspect of the present invention relates to a CMP polishing solution containing abrasive grains, an iron ion supplying agent, an organic acid, an oxidizing agent, and an aqueous liquid medium, in which the abrasive grains include silica particles having sulfo groups and silica particles not having sulfo groups.

According to the CMP polishing solution of the above-described aspect, a tungsten material can be polished at a high polishing rate, and the shelf life of the stock solution can be lengthened.

A ratio of a content of the silica particles not having sulfo groups with respect to a content of the silica particles having sulfo groups may be 0.10 to 10, may be 0.70 to 1.55, or may be 1.40 to 1.55.

A ratio of a number of molecules of the organic acid dissociated with respect to one atom of iron ion may be 2 or greater.

The polishing solution may further include an anticorrosive agent. The anticorrosive agent may include at least one selected from the group consisting of an azole compound and an amino acid, which do not have either or both of a thiol group and a carbon-carbon unsaturated bond, and may include at least one selected from the group consisting of 1,2,4-triazole, 4-amino-1,2,4-triazole, glycine, and 6-aminohexanoic acid.

The polishing solution may be a polishing solution used for a base body including a first portion formed from an insulating material and a second portion provided on the first portion and formed from a tungsten material, to polish at least the second portion.

Another aspect of the present invention relates to a stock solution that provides the polishing solution of the above-described aspect by being diluted two-fold or more with an aqueous liquid medium. According to such a stock solution, the cost required for transportation and storage can be reduced.

Another aspect of the present invention relates to a method for polishing a base body, the method including: a step of preparing a base body including a first portion formed from an insulating material and a second portion provided on the first portion and formed from a tungsten material; a step of disposing the base body on a polishing pad such that the polishing pad faces a surface of the second portion on the opposite side from the first portion; and a step of supplying the polishing solution of the above-described aspect or a polishing solution obtained by diluting the stock solution of the above-described aspect two-fold or more with an aqueous liquid medium, between the polishing pad and the base body, while polishing at least the second portion by moving the polishing pad and the base body relative to each other. According to this method, it is possible to polish a tungsten material at an excellent polishing rate with high selectivity to an insulating material.

### Advantageous Effects of Invention

According to the present invention, an object of the invention is to provide a CMP polishing solution that is likely to have a long shelf life in the state of being a stock solution and has a high polishing rate for a tungsten material, a stock solution from which the CMP polishing solution can be obtained, and a polishing method using the CMP polishing solution or using a polishing solution obtained from the stock solution.

### BRIEF DESCRIPTION OF DRAWINGS

FIG. 1 is schematic cross-sectional views illustrating a polishing method according to an embodiment.

### DESCRIPTION OF EMBODIMENTS

In the present specification, the “polishing rate for material A” and the “polishing rate with respect to material A” mean the rate at which a substance made of the material A is removed by polishing. In the present specification, a numerical value range indicated using the term “to” represents a range including the numerical values described before and after the term “to” as the minimum value and the maximum value, respectively. With regard to a numerical value range described stepwise in the present specification, the upper limit value or lower limit value of a numerical value range of a certain stage may be replaced with the upper limit value or lower limit value of a numerical value range of another stage. Regarding a material described as an example in the present specification, unless particularly stated otherwise, one kind thereof can be used alone, or two or more kinds thereof can be used in combination. In the present specification, the “pH” is defined as the pH when the temperature of the object of measurement is 25° C.

Hereinafter, suitable embodiments of the present invention will be described. However, the present invention is not intended to be limited to the following embodiments.

### <CMP Polishing Solution>

A polishing solution of an embodiment is a polishing solution used for a chemical mechanical polishing (CMP) method (CMP polishing solution). The polishing solution contains abrasive grains, an iron ion supplying agent, an organic acid, an oxidizing agent, and an aqueous liquid medium. With regard to this CMP polishing solution, the abrasive grains include silica particles having sulfo groups and silica particles not having sulfo groups.

According to the polishing solution of the above-described embodiment, there is provided an effect that a tungsten material can be polished at a high polishing rate, and it is possible to extend the shelf life of the stock solution. It is a highly unexpected result that such an effect is obtained by the composition of the above-described polishing solution. The reason why such an effect is obtained is not clearly understood; however, one of the reasons is speculated to be that agglomeration of silica particles is suppressed by using silica particles having sulfo groups and silica particles not having sulfo groups in combination.

Incidentally, in a first polishing step in a wiring forming method according to a damascene method, not only a tungsten film but also a barrier film and an insulating film may be polished. The CMP polishing solution used in the first polishing step may be required to have not only an excellent polishing rate for a tungsten material for the purpose of improving the throughput, but also an excellent ratio of the polishing rate for a tungsten material with respect to the polishing rate for an insulating material (polishing rate of tungsten material/polishing rate for insulating material; hereinafter, also simply referred to as “polishing rate ratio”) in order to obtain excellent planarity in the subsequent second polishing step, or in order to suppress the insulating film from being polished too thin, which would result in excessively decreased insulation between wires. In this regard, the polishing solution of the above-described embodiment also tends to be excellent in terms of the ratio of the polishing rate for a tungsten material with respect to the polishing rate for an insulating material.

From the viewpoint of preventing the etching rate of the tungsten material from becoming too high, and from the viewpoint of providing the above-described effects of the present invention more significantly, the pH of the CMP polishing solution is preferably 6.0 or less, more preferably 5.8 or less, and even more preferably 5.6 or less. The pH of the CMP polishing solution may be 5.4 or less, 5.2 or less, 5.0 or less, or 4.8 or less. The pH of the CMP polishing solution is, for example, 3.5 or greater, and from the viewpoint of further suppressing the polishing rate for the insulating material and obtaining a higher polishing rate ratio, the pH is preferably 4.0 or greater, more preferably 4.2 or greater, and even more preferably 4.5 or greater. From these viewpoints, the pH of the CMP polishing solution may be 3.5 to 6.0, 4.0 to 6.0, 4.2 to 5.8, or 4.5 to 5.6. The pH of the CMP polishing solution can be measured by the method described in the Examples.

### (Abrasive Grains)

The abrasive grains include silica particles having sulfo groups and silica particles not having sulfo groups. The silica particles are particles substantially composed of silica, and the content of silica in the silica particles is, for example, 80% by mass or more, 90% by mass or more, or 95% by mass or more.

Examples of the silica particles include fumed silica, fused silica, and colloidal silica. From the viewpoint that it is less likely to cause defects such as scratches on the surface of the polishing object after polishing, and the planarity of the surface to be polished can be further improved, colloidal silica is preferred.

The sulfo group may exist as an anion in the polishing solution and may be negatively charged. In a case where the polishing solution includes silica particles having such a functional group, that is, in a case where the stock solution includes silica particles having such a functional group, the shelf life of the stock solution is excellent. This is speculated to be because even when the repulsive force between silica particles due to the surface potential of some silica particles is small, in a case where at least some of the other silica particles have a sulfo group, which increases the repulsive force due to the surface potential, silica particles having a large repulsive force can penetrate between silica particles having a small repulsive force and increase the repulsive force between the silica particles, thereby suppressing agglomeration.

The sulfo group is, for example, bonded to silica on the surface of the silica particles. The sulfo group may be directly bonded (for example, covalent bonding) to silica, or may be indirectly bonded to silica by allowing a group other than the sulfo group in the compound having a sulfo group to be bonded to silica. As a compound having such a sulfo group, for example, a compound that is bonded to silica particles in a structure represented by the following Formula (1) may be mentioned:

[Chemical Formula 1]

SP—R¹-(Q)ₙ (1)

[wherein in Formula (1), SP represents a silica particle; R¹ represents an alkyl group having 0 or more carbon atoms and having a valence of n+1; Q represents a sulfo group; and n represents an integer of 1 or greater (for example, 1 to 3). When R¹ has 0 carbon atoms, this indicates that Q is directly bonded to the silica particle (SP) (in this case, n is 1). R¹ may be linear or branched.

The silica particles having sulfo groups can be obtained by modifying particles containing silica with a compound having a sulfo group. Examples of a modification method include a method of reacting particles containing silica with a compound having a sulfo group by utilizing the reactivity of a hydroxyl group on the surface of the particles containing silica.

The ratio of the content of the silica particles not having sulfo groups with respect to the content of the silica particles having sulfo groups may be 0.10 or greater, 0.30 or greater, 0.70 or greater, or 1.40 or greater, from the viewpoint of improving the polishing rate for tungsten. The ratio of the content of the silica particles not having sulfo groups with respect to the content of the silica particles having sulfo groups may be 10 or less, 5 or less, or 1.55 or less, from the viewpoint of improving the shelf life of the stock solution. From these viewpoints, the ratio of the content of the silica particles not having sulfo groups with respect to the content of the silica particles having sulfo groups may be 0.10 to 10, 0.30 to 5, 0.70 to 1.55, or 1.40 to 1.55. Incidentally, the above-described “content of the silica particles having sulfo groups” includes the amount of sulfo groups.

The content of the silica particles is, for example, 0.05% by mass or more based on the total mass of the polishing solution, and from the viewpoint that the polishing solution obtains a more excellent polishing rate for a tungsten material, and from the viewpoint that the polishing rate ratio is excellent, the content is preferably 0.3% by mass or more, more preferably 0.5% by mass or more, and even more preferably 0.7% by mass or more. From the viewpoint of more easily suppressing a decrease in the shelf life due to agglomeration of the silica particles, and from the viewpoint of easily obtaining a more excellent polishing rate for a tungsten material with the polishing solution, the content of the silica particles is 10.0% by mass or less, more preferably 7.0% by mass or less, and even more preferably 5.0% by mass or less, based on the total mass of the polishing solution. From these viewpoints, the content of the silica particles may be, for example, 0.05% to 10% by mass, 0.3% to 10% by mass, 0.5% to 7.0% by mass, or 0.7% to 5.0% by mass, based on the total mass of the polishing solution. The above-described “content of the silica particles” includes the amount of sulfo groups.

From the viewpoint of obtaining a more excellent polishing rate of the polishing solution for a tungsten material, the average particle size of the silica particles is preferably 200 nm or less, more preferably 170 nm or less, and even more preferably 150 nm or less. The average particle size of the silica particles may be 120 nm or less, 100 nm or less, 90 nm or less, or 80 nm or less. The average particle size of the silica particles is, for example, 40 nm or greater, and from the viewpoint of obtaining a more excellent polishing rate for a tungsten material and from the viewpoint of having an excellent polishing rate ratio, the average particle size is preferably 50 nm or greater, more preferably 60 nm or greater, and even more preferably 70 nm or greater. From these viewpoints, the average particle size of the silica particles may be, for example, 40 to 200 nm, 50 to 200 nm, 60 to 170 nm, or 70 to 150 nm.

The average particle size of the above-described silica particles can be measured at 25° C. using a device manufactured by Nihon Rufuto Co., Ltd. (product name: DC24000), which is a centrifugal-type particle size distribution meter. Regarding the measurement of the average particle size, the silica particles in the stock solution and the polishing solution may be measured, or the silica particles before being blended into the stock solution and the polishing solution may be diluted with water to the same concentration as the concentration of the polishing solution and then measured.

From the viewpoint that the effects of the present invention are more easily obtained, the surface potential of the silica particles is, for example, 0 to −50 mV.

The polishing solution may include abrasive grains other than silica particles, as long as the effects of the present invention are not inhibited. The content of the abrasive grains other than silica particles may be 10% by mass or less, 5% by mass or less, or 1% by mass or less, based on the total mass of the abrasive grains.

### (Iron Ion Supplying Agent)

The iron ion supplying agent supplies iron ions into the CMP polishing solution. The iron ions are preferably ferric ions. The iron ion supplying agent is, for example, a salt of iron and may exist in the polishing solution in a state of having been dissociated into an iron ion and an anionic component derived from the iron ion supplying agent. That is, the polishing solution containing the iron ion supplying agent includes iron ions. In a case where the CMP polishing solution contains an iron ion supplying agent, that is, in a case where the CMP polishing solution includes iron ions, the polishing rate for a tungsten material tends to further improve. Incidentally, the iron ion supplying agent may function as an oxidizing agent; however, a compound corresponding to both the iron ion supplying agent and the oxidizing agent is considered to correspond to the iron ion supplying agent in the present specification.

The iron ion supplying agent may be an inorganic salt or an organic salt. Examples of the inorganic salt containing iron ions include iron nitrate, iron sulfate, iron boride, iron chloride, iron bromide, iron iodide, iron phosphate, and iron fluoride. Examples of the organic salt containing iron ions include iron triformate, iron diformate, iron acetate, iron propionate, iron oxalate, iron malonate, iron succinate, iron malate, iron glutarate, iron tartrate, iron lactate, and iron citrate. These inorganic salts and organic salts may contain ligands such as ammonium and water or may be hydrates or the like. The iron ion supplying agents may be used singly, or two or more kinds thereof may be used in combination. From the viewpoint of causing relatively little contamination to the polishing device and the base body and being inexpensive and easily available, it is preferable that the iron ion supplying agent includes at least one selected from the group consisting of iron nitrate and hydrate of iron nitrate.

The content of the iron ion supplying agent may be adjusted such that the content of iron ions in the polishing solution falls within the following range. From the viewpoint of further improving the polishing rate for a tungsten material, the content of iron ions is preferably 0.0003% by mass or more, more preferably 0.0005% by mass or more, and even more preferably 0.001% by mass or more, based on the total mass of the polishing solution. From the viewpoint that decomposition and degeneration of the oxidizing agent and the like are less likely to occur, and changes in the polishing rate for a tungsten material after the CMP polishing solution is stored at room temperature (for example, 25° C.) are more easily suppressed (that is, having a more excellent pot life), the content of iron ions is preferably 0.1% by mass or less, more preferably 0.05% by mass or less, and even more preferably 0.010% by mass or less, based on the total mass of the polishing solution. From these viewpoints, the content of iron ions may be, for example, 0.0003% to 0.1% by mass, 0.0005% to 0.05% by mass, or 0.001% to 0.010% by mass, based on the total mass of the polishing solution.

### (Organic Acid)

The organic acid is a compound represented by the following Formula (2):

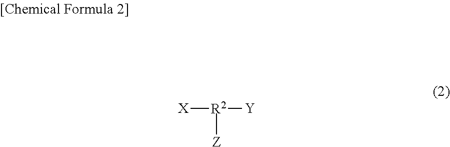

[wherein in Formula (2), R² represents a divalent alkyl group (alkylene group) having 1 or more carbon atoms; X, Y, and Z each represent hydrogen, or an acidic group such as a hydroxy group, a carboxy group, a phospho group, a sulfo group, a boron group, or a nitric acid group; and at least one of X, Y, and Z is an acidic group other than a hydroxy group (for example, a carboxy group, a phospho group, a sulfo group, a boron group, or a nitric acid group).

When the polishing solution includes the organic acid, the oxidizing agent included in the polishing solution is easily maintained in a stabilized state, and the effect of improving the polishing rate for a tungsten material is stably provided. Particularly, in a polishing solution containing iron ions and an oxidizing agent, the oxidizing agent is decomposed by iron ions, and other additives (for example, an anticorrosive agent) are degenerated at the time of decomposition of the oxidizing agent, so that the pot life of the polishing solution tends to decrease; however, when the polishing solution includes the organic acid, the decomposition of the oxidizing agent can be suppressed. The organic acid may be contained in the polishing solution as a pH adjusting agent.

The reason why the above-described effects are obtained by the organic acid is not clearly understood; however, it is speculated that the organic acid is dissociated in the polishing solution, and the dissociated organic acid chelates iron ions, thereby suppressing the decomposition of the oxidizing agent by the iron ions. Here, the term “dissociation” means that a proton (H⁺) is separated from at least one acid group (for example, a carboxy group (—COOH)) carried by the organic acid in the polishing solution, and the acid group exists in the form of anion (for example, —COO⁻).

From the viewpoint that the above-described effects are easily provided, the acid group of the organic acid is preferably a carboxy group.

From the viewpoint of making it easier to maintain the oxidizing agent more stably and further stabilizing the polishing rate for a tungsten material, it is preferable that the organic acid does not have a carbon-carbon unsaturated bond. The reason why the stability of the oxidizing agent improves when the organic acid does not have a carbon-carbon unsaturated bond, is not clearly understood; however, one of the reasons is thought to be that since the reactivity of a carbon-carbon unsaturated bonding part is relatively high, when the organic acid does not have a carbon-carbon unsaturated bond, degeneration caused by the reaction with the oxidizing agent in the polishing solution does not occur.

The organic acid is preferably a divalent or trivalent organic acid. Here, the term “divalent or trivalent” means the number of acid groups carried by the organic acid. When the organic acid is divalent or trivalent, an iron ion is chelated by a plurality of acid groups (for example, two or more dissociated acid groups) carried by the organic acid, and the oxidizing agent tends to be more easily maintained stable.

From the above-described viewpoints, the organic acid is preferably a divalent or trivalent organic acid that does not have a carbon-carbon unsaturated bond.

Specific examples of a preferred organic acid include malonic acid, succinic acid, adipic acid, glutaric acid, and malic acid. These organic acids may be used singly, or two or more kinds thereof may be used in combination. The dissociation ratios of these organic acids at pH 5 are as follows.

TABLE 1

| | Malonic | Succinic | Adipic | Glutaric | Malic |
|---|---|---|---|---|---|
| | acid | acid | acid | acid | acid |
| Dissociation | 65 | 60 | 61 | 62 | 34 |
| ratio (%) | | | | | |

The ratio of the number of molecules of the organic acid dissociated with respect to one atom of iron ion contained in the polishing solution is preferably 2 or greater, more preferably 4 or greater, and even more preferably 6 or greater, from the viewpoint of sufficiently chelating iron ions and enhancing the stability of the oxidizing agent. The ratio of the number of molecules of the dissociated organic acid may be 200 or less.

The content of the organic acid is, for example, 0.6% by mass or less based on the total mass of the polishing solution, and from the viewpoint that agglomeration of silica particles in the stock solution is suppressed, and a more excellent shelf life is likely to be obtained, the content is preferably 0.5% by mass or less, more preferably 0.3% by mass or less, and even more preferably 0.2% by mass or less. From the viewpoint of sufficiently chelating iron ions and increasing the stability of the oxidizing agent, the content of the organic acid is preferably 0.0001% by mass or more, more preferably 0.0005% by mass or more, and even more preferably 0.01% by mass or more. From these viewpoints, the content of the organic acid may be, for example, 0.0001% to 0.6% by mass, 0.0001% to 0.5% by mass, 0.0005% to 0.3% by mass, or 0.001% to 0.02% by mass, based on the total mass of the polishing solution.

From the viewpoint of allowing the organic acid to sufficiently chelate iron ions as described above and increasing the stability of the oxidizing agent, it is preferable that the content of the organic acid is adjusted such that the ratio of the number of molecules of the organic acid with respect to one atom of iron ion falls within the above-described range. For example, in a case where malonic acid is used as the organic acid, the content of iron ions is set to 0.001% by mass, and the pH of the polishing solution is set to 5.0, the blending amount of malonic acid is preferably 0.0057% by mass (two molecules of malonic acid dissociated with respect to 1 atom of iron ion) or more. Incidentally, with regard to the above-described blending amount, the molar amount of iron ions was calculated from the atomic weight and the blending amount assuming that the molecular weight of malonic acid was 104.06, the dissociation ratio was 65%, and the atomic weight of iron ion was 55.85, and the blending amount of malonic acid was determined by calculating from the molar amount of iron ions, the molecular weight and dissociation ratio of malonic acid, and the blending ratio of malonic acid with respect to one atom of iron ion (two molecules of dissociated malonic acid).

### (Aqueous Liquid Medium)

The aqueous liquid medium is not particularly limited; however, water such as deionized water or ultrapure water is preferred. The content of the aqueous liquid medium may be the balance of the polishing solution excluding the contents of other constituent components and is not particularly limited.

### (Oxidizing Agent)

The oxidizing agent contributes to an improvement in the polishing rate for a tungsten material. That is, when the polishing solution contains an oxidizing agent, the polishing rate for a tungsten material tends to further improve. Furthermore, the oxidizing agent does not have to be added to the stock solution. That is, the oxidizing agent may be added when diluting the stock solution.

Examples of the oxidizing agent include hydrogen peroxide (H₂O₂), potassium periodate, ammonium persulfate, hypochlorous acid, and ozone water. These may be used singly, or two or more kinds thereof may be used in combination. Hydrogen peroxide is preferably used as the oxidizing agent, from the viewpoint that it is relatively stable even after addition, and there is no concern about contamination by halides and the like.

From the viewpoint of easily obtaining an effect of further improving the polishing rate, the content of the oxidizing agent is preferably 0.1% by mass or more, more preferably 1.0% by mass or more, and even more preferably 2% by mass or more, based on the total mass of the polishing solution. From the viewpoint of easily suppressing the etching rate for a tungsten material, the content of the oxidizing agent is preferably 10.0% by mass or less, more preferably 7.0% by mass or less, and even more preferably 5.0% by mass or less, based on the total mass of the polishing solution.

### (Anticorrosive Agent)

The polishing solution may further include an anticorrosive agent, from the viewpoint of suppressing the etching rate for a tungsten material. As the anticorrosive agent, general azole-based compounds, amino acids, and the like can be used. However, from the viewpoint of preventing a decrease in the pot life, an azole-based compound or amino acid that does not have either or both of a thiol group and a carbon-carbon unsaturated bond is preferable, and an azole-based compound or amino acid that does not have a thiol group and a carbon-carbon unsaturated bond is more preferable. That is, in the present embodiment, it is preferable that the polishing solution includes at least one selected from the group consisting of an azole compound not having a thiol group, an amino acid not having a thiol group, an azole compound not having a carbon-carbon unsaturated bond, an amino acid not having a carbon-carbon unsaturated bond, an azole compound not having a thiol group and a carbon-carbon unsaturated bond, and an amino acid not having a thiol group and a carbon-carbon unsaturated bond, and it is more preferable that the polishing solution includes at least one selected from the group consisting of an azole compound not having a thiol group and a carbon-carbon unsaturated bond, and an amino acid not having a thiol group and a carbon-carbon unsaturated bond. When an azole-based compound having a thiol group and/or a carbon-carbon unsaturated bond, or an amino acid having a thiol group and/or a carbon-carbon unsaturated bond is used, the etching rate tends to increase, and the pot life tends to decrease. The reason for this is not clearly understood; however, one of the reasons is thought to be that when the oxidizing agent in the polishing solution reacts with a thiol group and/or a carbon-carbon unsaturated bonding site, the oxidizing agent and the anticorrosive agent are degenerated.

Examples of the anticorrosive agent include glycine, 6-aminohexanoic acid, 1,2,4-triazole, 1H-tetrazole, 1,2,4-triazole-3-carboxamide, 3-amino-1,2,4-triazole, 4-amino-1,2,4-triazole, 5-methyltetrazole, 5-amino-1H-tetrazole, 1H-tetrazole-1-acetic acid, 1,5-pentamethylenetetrazole, 3,5-diamino-1,2,4-triazole, 1H-1,2,3-triazole, 1,2,4-triazolecarboxylic acid ethyl ester, methyl 1,2,4-triazole-3-carboxylate, and derivatives thereof. Among these, from the viewpoint of easily suppressing the etching rate for a tungsten material, 1,2,4-triazole, 4-amino-1,2,4-triazole, glycine, and 6-aminohexanoic acid are preferred. The anticorrosive agents may be used singly, or two or more kinds thereof may be used in combination.

From the viewpoint of suppressing the etching rate for a tungsten film, the content of the anticorrosive agent is preferably 0.003% by mass or more, more preferably 0.005% by mass or more, even more preferably 0.01% by mass or more, and particularly preferably 0.02% by mass or more, based on the total mass of the polishing solution. From the viewpoint of easily obtaining an effect of increasing the polishing rate for a tungsten material, the content of the anticorrosive agent is preferably 0.5% by mass or less, more preferably 0.3% by mass or less, and even more preferably 0.2% by mass or less, based on the total mass of the polishing solution. From these viewpoints, the content may be 0.003% to 0.5% by mass, 0.005% to 0.3% by mass, 0.01% by mass to 0.3% by mass, or 0.02% by mass to 0.2% by mass.

### (pH Adjusting Agent)

As the pH adjusting agent, known organic acids, inorganic acids, organic bases, inorganic bases, and the like can be used.

As an organic acid, oxalic acid, malonic acid, tartaric acid, succinic acid, glutaric acid, adipic acid, pimelic acid, suberic acid, malic acid, citric acid, butanetetracarboxylic acid, and the like can be used. As an inorganic acid, sulfuric acid, nitric acid, phosphoric acid, hydrochloric acid, and the like can be used. Regarding these organic acids and inorganic acids, two or more kinds thereof may be used in combination.

As an organic base, methylamine, ethylamine, propylamine, monoethanolamine, tetramethylammonium hydroxide, and the like can be used. As an inorganic base, ammonia, sodium hydroxide, potassium hydroxide, and the like can be used. Regarding these organic bases and inorganic bases, two or more kinds thereof may be used in combination.

### (Other Components)

The polishing solution may include components other than the above-mentioned components, as long as the effects of the present invention are not inhibited. For example, the polishing solution may include an adjusting agent, such as an anionic surfactant such as polyacrylic acid, a cationic surfactant such as polyethyleneimide, or a nonionic surfactant such as polyethylene glycol, polypropylene glycol, polyglycerin, or polyacrylamide.

The polishing solution described above can be widely used as a polishing solution used for CMP; however, the polishing solution is particularly suitable as a CMP polishing solution for polishing a tungsten material. Specifically, for example, the polishing solution is used for a base body (for example, a substrate) including a first portion formed from an insulating material and a second portion provided on the first portion and formed from a tungsten material, for polishing at least the second portion. The polishing solution may also be used to polish the first portion in addition to the second portion.

The first portion may be, for example, a part or the entirety of a film containing an insulating material (insulating film). Examples of the insulating material include a silicon-based insulating material and an organic polymer-based insulating material. Examples of the silicon-based insulating material include silicon oxide (for example, silicon dioxide obtained using tetraethyl orthosilicate (TEOS)), silicon nitride, tetraethoxysilane, fluorosilicate glass, trimethylsilane, organosilicate glass obtained using dimethoxydimethylsilane as a starting raw material, silicon oxynitride, hydrogenated silsesquioxane, silicon carbide, and silicon nitride. Examples of the organic polymer-based insulating material include a wholly aromatic low-dielectric constant insulating material.

The second portion may be, for example, a part or the entirety of a film containing a tungsten material (tungsten film). Examples of the tungsten material include tungsten, tungsten nitride, tungsten silicide, and a tungsten alloy. The content of tungsten in the tungsten material is preferably 80% by mass or more, more preferably 90% by mass or more, and even more preferably 95% by mass or more.

The base body may further have, between the first portion and the second portion, a third portion formed from a barrier material. The polishing solution may be used to polish the third portion in addition to the second portion (and also the first portion). The third portion may be, for example, a part or the entirety of a film containing a barrier material (barrier film). Examples of the barrier material include tantalum, tantalum nitride, titanium, and titanium nitride.

As the base body such as described above, a substrate that is applied to a wiring formation process according to a damascene method may be mentioned. In other words, the CMP polishing solution of the above-described embodiment is suitable as a CMP polishing solution used for a wiring formation process according to a damascene method.

### [Stock Solution]

The CMP polishing solution can be prepared by, for example, mixing abrasive grains including the above-mentioned silica particles, an iron ion supplying agent, an organic acid, an oxidizing agent, and an aqueous liquid medium, and dispersing the mixture. The obtained CMP polishing solution can be concentrated by removing a portion of the aqueous liquid medium and stored as a stock solution used by being diluted two-fold or more with an aqueous liquid medium such as water at the time of use. When prepared as a stock solution, an oxidizing agent may not be added. In this case, an oxidizing agent may be added when a polishing solution is obtained from the stock solution. The stock solution may be prepared into a CMP polishing solution by diluting with a liquid medium immediately before polishing and adding an oxidizing agent as needed, or when polishing a base body, the stock solution, an aqueous liquid medium, and an oxidizing agent as needed may be supplied onto a polishing platen, and a CMP polishing solution may be prepared on the polishing platen.

Since a higher dilution factor implies a higher effect of suppressing costs associated with transportation, storage, and the like, the dilution factor of the stock solution is preferably two-fold or more, and more preferably three-fold or more. Furthermore, the upper limit of the dilution factor is not particularly limited; however, the upper limit is preferably ten-fold or less, more preferably seven-fold or less, and even more preferably five-fold or less. When the dilution factor is equal to or less than these upper limit values, the content of the abrasive grains or each of the components included in the stock solution is prevented from becoming too high, and the stability of the stock solution during storage tends to be easily maintained. Incidentally, when the dilution factor is designated as d, each of the content percentages of the abrasive grains, each component, and the like in the stock solution is d-fold of each of the content percentages of the abrasive grains and the organic acid in the CMP polishing solution.

### <Polishing Method>

The polishing method of the present embodiment includes a step of removing a material to be polished (for example, a tungsten material or the like) by CMP using the polishing solution of the above-described embodiment or a polishing solution obtained by diluting the stock solution of the above-described embodiment. In the polishing method of the present embodiment, for example, a base body (substrate or the like) having a material to be polished is polished using a polishing device. As the polishing device, for example, a general polishing device including: a polishing platen, to which a polishing pad (polishing cloth) is attached, and which is equipped with a motor whose speed of rotation is variable or the like; and a holder (head) for holding a base body, can be used. The polishing pad is not particularly limited; however, a general nonwoven fabric, polyurethane foam, a porous fluororesin, and the like can be used.

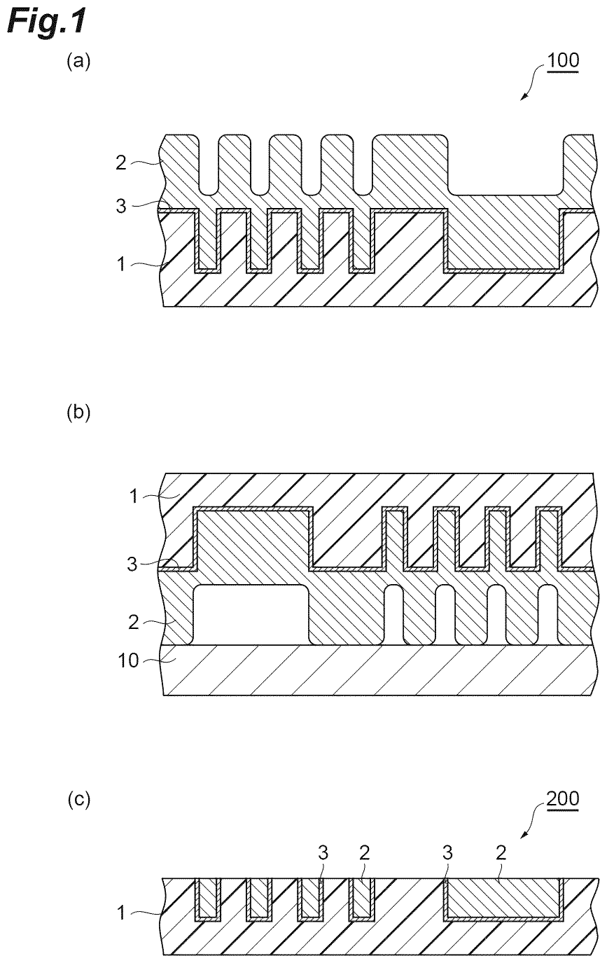

The polishing method of the present embodiment includes, for example, a step (preparation step) of preparing a base body having a material to be polished, a step (disposition step) of disposing the base body on a polishing pad, and a step (polishing step) of polishing the base body using a polishing solution. In the following description, an embodiment of using the above-mentioned base body including a first portion, a second portion, and a third portion as the base body having a material to be polished, will be described as an example, and the details of the polishing method of the present embodiment will be described using FIG. 1.

First, as shown in FIG. 1(a), a base body (substrate) 100 that includes a first portion 1 formed from an insulating material and having grooves formed on the surface, a second portion 2 provided on the first portion, and a third portion 3 provided between the first portion 1 and the second portion 2, is prepared as a base body before polishing (preparation step). The second portion 2 is formed from a tungsten material and is deposited so as to fill the recess parts formed by the first portion and the third portion. The third portion 3 is formed from a barrier material so as to conform to the unevenness of the surface of the first portion 1.

Next, as shown in FIG. 1(b), the base body 100 is disposed on a polishing pad 10 such that the polishing pad 10 faces a surface of the second portion 2 on the opposite side from the first portion 1 (disposition step).

Next, in a state in which the base body 100 is pressed against the polishing pad 10, the CMP polishing solution of the above-described embodiment is supplied between the polishing pad 10 and the base body 100, and at the same time, at least the second portion is polished by moving the polishing pad 10 and the base body 100 relative to each other (polishing step). At this time, the second portion 2 and the third portion 3 may be removed until the first portion 1 is exposed, or overpolishing of excessively polishing the first portion 1 may be carried out. Planarity of the surface to be polished after polishing can be increased by such overpolishing. Through the above-described operations, a base body 200 shown in FIG. 1(c) is obtained.

The polishing conditions are not particularly limited; however, it is preferable to set the speed of rotation of the polishing platen to 200 rpm or less so that the base body does not fly out. In the case of using a base body having a tungsten material, the polishing pressure is preferably 3 to 100 kPa. From the viewpoint of obtaining satisfactory uniformity of the polishing rate within the polishing surface and obtaining satisfactory planarity, it is more preferable that the polishing pressure is 5 to 50 kPa. It is preferable that the CMP polishing solution is continuously supplied onto the polishing pad using a pump or the like during the process of polishing. This supply amount is not limited; however, it is preferable that the surface of the polishing pad is covered with the polishing solution all the time. In order to perform CMP while maintaining the surface state of the polishing pad identical all the time, it is preferable to perform a step of conditioning the polishing cloth before polishing and/or during polishing. For example, conditioning of the polishing pad is performed with a liquid containing at least water using a dresser having diamond particles attached thereto. Subsequently, it is preferable that the polishing method of the present embodiment is carried out, and then a substrate washing step is carried out.

### EXAMPLES

Hereinafter, the present invention will be specifically described by way of Examples; however, the present invention is not intended to be limited by these Examples.

### (Preparation of Silica Particles)

In the following Examples and Comparative Examples, colloidal silica (silica particles A, B, C, D, E, and F) having the average particle sizes indicated in Table 2 were used as silica particles. The average particle sizes of the silica particles shown in Table 2 were measured at 25° C. using a device manufactured by Nihon Rufuto Co., Ltd. (product name: DC24000), which is a centrifugal-type particle size distribution meter. For the measurement, measurement samples obtained by diluting the silica particles with pure water such that the abrasive grain concentration (silica particle concentration) was 0.5% to 3.0% by mass, were used. As shown in Table 2, among the silica particles A, B, C, D, E, and F, silica particles A and B are silica particles having sulfo groups.

TABLE 2

| Silica | | | | | | |
|---|---|---|---|---|---|---|
| particles | A | B | C | D | E | F |
| Average | 48 | 110 | 50 | 80 | 110 | 35 |
| particle | | | | | | |
| size (nm) | | | | | | |
| Sulfo group | Present | Present | Absent | Absent | Absent | Absent |

### Example 1

Malonic acid (0.096% by mass), iron nitrate nonahydrate (0.024% by mass), silica particles A (1.2% by mass) as silica particles 1, and silica particles D (1.8% by mass) as silica particles 2 were blended in deionized water, and the pH of the mixture was adjusted with an appropriate amount of an aqueous ammonia solution to obtain a stock solution 1 having a pH of 4.9. The numerical values (unit: % by mass) indicated within parentheses are all the contents of the various components in the stock solution, based on the total mass of the stock solution 1.

Next, 33.3 parts by mass of the stock solution 1, 63.7 parts by mass of deionized water, and 3.0 parts by mass of hydrogen peroxide were mixed to obtain a CMP polishing solution 1. That is, the stock solution 1 was diluted 3-fold. The content of each component in the CMP polishing solution 1 was such that the content of silica particles A was 0.4% by mass, the content of silica particles D was 0.6% by mass, the content of malonic acid was 0.032% by mass, the content of iron nitrate nonahydrate was 0.008% by mass, and the content of hydrogen peroxide was 3.0% by mass. Furthermore, the pH of the CMP polishing solution was 5.0.

### Examples 2 and 3

Stock solutions 2 and 3 that were 3-fold concentrated and CMP polishing solutions 2 and 3 were produced in the same manner as in Example 1, except that the silica particles indicated in Table 3 were used as the silica particles, and the blending amount of the silica particles was adjusted such that the content of the silica particles in the polishing solution would have the value indicated in Table 3.

### Example 4

A 3-fold concentrated stock solution 4 and a CMP polishing solution 4 were produced in the same manner as in Example 1, except that in addition to the silica particles A, silica particles D, malonic acid, and iron nitrate nonahydrate, glycine was blended as an anticorrosive agent. The blending amount of the anticorrosive agent was adjusted such that the content in the polishing solution would be 0.03% by mass.

### Example 5

A 3-fold concentrated stock solution 5 and a CMP polishing solution 5 were produced in the same manner as in Example 4, except that 1,2,4-triazole was used as an anticorrosive agent in place of glycine, and the blending amount of the anticorrosive agent was changed. The blending amount of the anticorrosive agent was adjusted such that the content in the polishing solution would be 0.024% by mass.

### Examples 6 to 8 and Comparative Examples 1 to 6

Stock solutions 6 to 8 and 10 to 15 that were 3-fold concentrated, and CMP polishing solutions 6 to 8 and 10 to 15 were produced in the same manner as in Example 1, except that the silica particles indicated in Table 4 and Table 5 were used as silica particles, and the blending amounts of the silica particles were adjusted such that the contents of the silica particles in the polishing solutions would have the values indicated in Table 4 and Table 5.

### Example 9

A 3-fold concentrated stock solution 9 and CMP polishing solution 9 were produced in the same manner as in Example 1, except that the blending amount of malonic acid was changed. The blending amount of malonic acid was adjusted such that the content in the polishing solution would be 0.6% by mass.

### <Evaluation>

### (Measurement of pH)

The pH of the stock solutions 1 to 15 and the CMP polishing solutions 1 to 15 was adjusted under the following conditions. The results are shown in Tables 3 to 5.

### [Measurement Conditions]

Measurement temperature: 25° C.
Measuring device: Product name: Model (F-51) of Horiba, Ltd.
Measurement method: A pH meter was subjected to three-point calibration using a phthalate pH standard solution (pH: 4.01), a neutral phosphate pH standard solution (pH: 6.86), and a borate pH standard solution (pH: 9.18) as pH standard solutions, subsequently the electrodes of the pH meter were placed in the stock solutions and the polishing solutions, and the pH after the solutions had been stabilized for 2 minutes or longer was measured using the above-described measuring device.

### (Measurement of Particle Size Distribution)

The average particle sizes of the silica particles in the CMP polishing solutions 1 to 15 were measured at 25° C. using a device manufactured by Nihon Rufuto Co., Ltd. (product name: DC24000), which is a centrifugal-type particle size distribution meter. The results are shown in Tables 3 to 5.

### (Measurement of Surface Potential)

The surface potentials of the silica particles in the CMP polishing solutions 1 to 15 were measured at 25° C. using Delsa Nano C manufactured by Beckman Coulter, Inc. Furthermore, when measuring the surface potential, hydrogen peroxide was not added to the CMP polishing solutions 1 to 15, and measurement was made by replacing the hydrogen peroxide portion with water. The results are shown in Tables 3 to 5.

### (Measurement of Dissociation Rate of Organic Acid)

The dissociation rate of the organic acid in the polishing solution was determined based on the following formula, and the ratio of the number of molecules of organic acid dissociated with respect to one atom of iron ion was calculated.

$$Dissociation rate ( \% ) of organic acid = ( 100 / 0.0112 ) \times A$$

$$[ A = 0.0112 \times B \times 10 \hat{} ( - {K}_{1} ) / ( B \hat{} 2 + B \times 10 \hat{} ( - {K}_{1} ) + 10 \hat{} ( - {K}_{1} ) \times 10 \hat{} ( - {K}_{2} ) ) ]$$

$$[ B = 10 \hat{} ( - pH ) ]$$

$$[ {K}_{1} , {K}_{2} = Dissociation constants of organic acid ]$$

### (Evaluation of Shelf Life)

100 mL each of the stock solutions 1 to 15 were placed in containers made of a resin and were stored for one month at 40° C. The average particle sizes of the silica particles before and after the storage were measured by the above-mentioned particle size distribution measurement, and the increase ratios of the average particle sizes were measured. The results are shown in Tables 3 to 5. The increase ratio of the average particle size is preferably less than 10%.

### (Evaluation of Polishing Rate)

The polishing rates for tungsten materials and insulating materials were measured using the CMP polishing solutions 1 to 15. The measurement of the polishing rate was carried out by polishing the following substrates for evaluation under the following polishing conditions.

### [Substrate for Polishing Rate Evaluation]

Substrate having a tungsten film: A 12-inch tungsten film substrate in which a tungsten film having a thickness of 700 nm was formed on a silicon substrate
Substrate having an insulating film: A 12-inch TEOS film substrate in which a TEOS (tetraethoxysilane) film having a thickness of 1000 nm was formed on a silicon substrate

### [Polishing Conditions]

Polishing pad: IC1010 (Nitta Haas, Inc.)
Polishing pressure: 20.7 kPa
Speed of rotation of platen: 93 rpm
Speed of rotation of head: 87 rpm
Supply amount of CMP polishing solution: 300 ml
Polishing time for tungsten film: 60 seconds
Polishing time for insulating film (TEOS film): 60 seconds

The polishing rate for the tungsten material was determined by converting the difference between the film thicknesses obtained before and after CMP of the tungsten film from the electric resistance values using a resistance measuring device VR-120/08S (manufactured by Hitachi Kokusai Electric, Inc.). The results are shown in Tables 3 to 5. In CMP under the same conditions, the polishing rate for the tungsten material is preferably 350 nm/min or greater.

The polishing rate for the insulating material (TEOS) was measured by measuring the difference between the film thicknesses before and after CMP of the insulating film (TEOS film) using an optical film thickness meter F50 (manufactured by Filmetrics). The results are shown in Tables 3 to 5. In CMP under the same conditions, the polishing rate for the insulating material is preferably 10 nm/min or less. Furthermore, it is preferable that the ratio r of the polishing rate for the tungsten material and the polishing rate for the insulating material (polishing rate for tungsten material/polishing rate for insulating material) is 30 or greater.

### (Evaluation of Etching Rate)

100 mL each of the CMP polishing solutions 1 to 15 were placed in containers made of a resin and were heated at 60° C. for 15 minutes. The above-mentioned 12-inch tungsten film substrate was cut into squares that measured 2 cm on each side, and the cut substrates were immersed for 3 minutes in a CMP polishing solution that had been heated at 60° C. Thereafter, the difference between the film thicknesses before and after immersion of the tungsten film was determined by converting from the electric resistance values using a resistance measuring device RT-80 (manufactured by NAPSON CORPORATION). The results are shown in Tables 3 to 5.

### (Evaluation of Pot Life)

As an index of the pot life, the maintenance ratio of the polishing rate for the tungsten material obtained after the CMP polishing solution had been stored for one week at room temperature, was evaluated. The maintenance ratio of the polishing rate for the tungsten material was determined from the polishing rate (R1) for the tungsten material measured immediately after (within 12 hours) the preparation of the CMP polishing solution and the polishing rate (R2) for the tungsten material measured in the same manner with the CMP polishing solution that had been stored at room temperature (25° C.) for one week, by the following formula. The results are shown in Table 3. The maintenance ratio of the polishing rate for the tungsten material is preferably 95% or greater.

Maintenance ratio (%) of polishing rate for tungsten material=100×(R1/R2)

TABLE 3

| | | | Example 1 | Example 2 | Example 3 | Example 4 | Example 5 |
|---|---|---|---|---|---|---|---|
| Stock solution | Type of stock solution | | 1 | 2 | 3 | 4 | 5 |
| | pH of stock solution | | 4.9 | 4.9 | 4.9 | 4.9 | 4.9 |
| | Dilution factor | | 3 | 3 | 3 | 3 | 3 |
| Polishing | Type of polishing solution | | 1 | 2 | 3 | 4 | 5 |
| solution | Silica | Type | A | A | B | A | A |
| | particles 1 | Content | 0.4 | 0.4 | 0.28 | 0.4 | 0.4 |
| | | (% by mass) | | | | | |
| | Silica | Type | D | E | C | D | D |
| | particles 2 | Content | 0.6 | 0.6 | 0.4 | 0.6 | 0.6 |
| | | (% by mass) | | | | | |
| | Ratio of silica particles | | 1.5 | 1.5 | 1.43 | 1.5 | 1.5 |
| | Average particle size of silica particles (nm) | | 75 | 82 | 81 | 76 | 76 |
| | Surface potential of silica particles (mV) | | −15 | −22 | −20 | −25 | −15 |
| | Malonic acid | Content | 0.032 | | | | |
| | | (% by mass) | | | | | |
| | Iron nitrate | Content | 0.008 | | | | |
| | nonahydrate | (% by mass) | | | | | |
| | Hydrogen | Content | 3 | | | | |
| | peroxide | (% by mass) | | | | | |
| | Glycine | Content | — | — | — | 0.03 | — |
| | | (% by mass) | | | | | |
| | 1,2,4-Triazole | Content | — | — | — | — | 0.024 |
| | | (% by mass) | | | | | |
| | Molar amount of organic acid (mmol) | | 0.308 | 0.308 | 0.308 | 0.308 | 0.308 |
| | Molar amount of iron ions (mmol) | | 0.02 | | | | |
| | Number of molecules of organic acid | | 10 | 10 | 10 | 10 | 10 |
| | with respect to 1 atom of iron ion | | | | | | |
| | pH | | 5 | | | | |
| Shelf life | Particle size increase ratio (%) | | 0 | 4 | 1 | 8 | 5 |
| Etching rate for W (nm/min) | | | 72 | 71 | 72 | 40 | 46 |
| Polishing | Immediately | Tungsten | 441 | 391 | 396 | 405 | 353 |
| rate | after blending | material | | | | | |
| (nm/min) | | Insulating | 7.9 | 7.2 | 3 | 6 | 6.5 |
| | | material (TEOS) | | | | | |
| | After one week | Tungsten | 432 | 383 | 380 | 390 | 350 |
| | | material | | | | | |

| | | | | | |
|---|---|---|---|---|---|
| Polishing rate ratio r | 56 | 54 | 132 | 68 | 54 |
| Polishing rate maintenance ratio (%) | 98 | 98 | 96 | 96 | 99 |

*In the table, the term “Ratio of silica particles” indicates the ratio of silica particles not having sulfo groups with respect to silica particles having sulfo groups.

TABLE 4

| | | | Example 6 | Example 7 | Example 8 | Example 9 |
|---|---|---|---|---|---|---|
| Stock solution | Type of stock solution | | 6 | 7 | 8 | 9 |
| | pH of stock solution | | 4.9 | 4.9 | 4.9 | 4.9 |
| | Dilution factor | | 3 | 3 | 3 | 3 |
| Polishing | Type of polishing solution | | 6 | 7 | 8 | 9 |
| solution | Silica | Type | A | A | B | A |
| | particles 1 | Content | 0.3 | 0.04 | 0.8 | 0.4 |
| | | (% by mass) | | | | |
| | Silica | Type | F | D | C | D |
| | particles 2 | Content | 0.3 | 0.03 | 0.7 | 0.6 |
| | | (% by mass) | | | | |
| | Ratio of silica particles | | 1 | 0.75 | 0.88 | 1.5 |
| | Average particle size of silica particles (nm) | | 40 | 60 | 82 | 76 |
| | Surface potential of silica particles (mV) | | −10 | −10 | 9 | −3 |
| | Malonic acid | Content | 0.032 | 0.032 | 0.032 | 0.6 |
| | | (% by mass) | | | | |
| | Iron nitrate | Content | 0.008 | | | |
| | nonahydrate | (% by mass) | | | | |
| | Hydrogen | Content | 3 | | | |
| | peroxide | (% by mass) | | | | |
| | Molar amount of organic acid (mmol) | | 0.308 | 0.308 | 0.308 | 5.76 |
| | Molar amount of iron ions (mmol) | | 0.02 | 0.02 | 0.02 | 0.02 |
| | Number of molecules of organic acid | | 10 | 10 | 10 | 187 |
| | with respect to 1 atom of iron ion | | | | | |
| | pH | | 5 | 5 | 3.5 | 5 |
| Shelf life | Particle size increase ratio (%) | | 2 | 0 | 2 | 58 |
| Etching rate for W (nm/min) | | | 65 | 65 | 62 | 95 |
| Polishing | Immediately | Tungsten | 140 | 173 | 404 | 353 |
| rate | after blending | material | | | | |
| (nm/min) | | Insulating | 8.5 | 5.5 | 24 | 15 |
| | | material (TEOS) | | | | |

| | | | | |
|---|---|---|---|---|
| Polishing rate ratio r | 16 | 31 | 17 | 24 |

*In the table, the term “Ratio of silica particles” indicates the ratio of silica particles not having sulfo groups with respect to silica particles having sulfo groups.

TABLE 5

| | | | Comparative | Comparative | Comparative | Comparative | Comparative | Comparative |
|---|---|---|---|---|---|---|---|---|
| | | | Example 1 | Example 2 | Example 3 | Example 4 | Example 5 | Example 6 |
| Stock | Type of stock solution | | 10 | 11 | 12 | 13 | 14 | 15 |
| solution | pH of stock solution | | 4.9 | 4.9 | 4.9 | 4.9 | 4.9 | 4.9 |
| | Dilution factor | | 3 | 3 | 3 | 3 | 3 | 3 |
| Polishing | Type of polishing solution | | 10 | 11 | 12 | 13 | 14 | 15 |
| solution | Silica | Type | C | C | C | D | E | F |
| | particles 1 | Content | 0.28 | 0.4 | 1.5 | 1.5 | 1.5 | 1.5 |
| | | (% by mass) | | | | | | |
| | Silica | Type | E | D | — | — | — | — |
| | particles 2 | Content | 0.4 | 0.6 | — | — | — | — |
| | | (% by mass) | | | | | | |
| | Average particle size of silica particles (nm) | | 83 | 74 | 52 | 83 | 113 | 39 |
| | Surface potential of silica particles (mV) | | −7 | −6 | 9 | 8 | 12 | 6 |
| | Malonic | Content | 0.032 | | | | | |
| | acid | (% by mass) | | | | | | |
| | Iron nitrate | Content | 0.008 | | | | | |
| | nonahydrate | (% by mass) | | | | | | |
| | Hydrogen | Content | 3 | | | | | |
| | peroxide | (% by mass) | | | | | | |
| | Molar amount of organic acid (mmol) | | 0.308 | 0.308 | 0.308 | 0.308 | 0.308 | 0.308 |
| | Molar amount of iron ions (mmol) | | 0.02 | 0.02 | 0.02 | 0.02 | 0.02 | 0.02 |
| | Number of molecules of organic acid | | 10 | | | | | |
| | with respect to 1 atom of iron ion | | | | | | | |
| | pH | | 5 | | | | | |
| Shelf life | Particle size increase ratio (%) | | 33 | 22 | 35 | 22 | 14 | 49 |
| | Etching rate for W (nm/min) | | 72 | 71 | 66 | 72 | 70 | 66 |
| Polishing | Immediately | Tungsten | 401 | 392 | 390 | 403 | 378 | 182 |
| rate | after blending | material | | | | | | |
| (nm/min) | | Insulating | 8.9 | 9.8 | 12 | 14.2 | 11.8 | 6 |
| | | material (TEOS) | | | | | | |

| | | | | | | |
|---|---|---|---|---|---|---|
| Polishing rate ratio r | 45 | 40 | 33 | 28 | 32 | 30 |

### REFERENCE SIGNS LIST

1: first portion, 2: second portion, 3: third portion, 10: polishing pad, 100, 200: substrate (base body).

1. A CMP polishing solution comprising:
abrasive grains;
an iron ion supplying agent;
an organic acid;
an oxidizing agent; and
an aqueous liquid medium,
wherein the abrasive grains include silica particles having sulfo groups and silica particles not having sulfo groups.

2. The CMP polishing solution according to claim 1, wherein a ratio of a content of the silica particles not having sulfo groups with respect to a content of the silica particles having sulfo groups is 0.10 to 10.

3. The CMP polishing solution according to claim 1, wherein a ratio of a content of the silica particles not having sulfo groups with respect to a content of the silica particles having sulfo groups is 0.70 to 1.55.

4. The CMP polishing solution according to claim 1, wherein a ratio of a content of the silica particles not having sulfo groups with respect to a content of the silica particles having sulfo groups is 1.40 to 1.55.

5. The CMP polishing solution according to claim 1, wherein a ratio of a number of molecules of the organic acid dissociated with respect to one atom of iron ion is 2 or greater.

6. The CMP polishing solution according to claim 1, further comprising an anticorrosive agent.

7. The CMP polishing solution according to claim 6, wherein the anticorrosive agent includes at least one selected from the group consisting of an azole compound and an amino acid, which do not have either or both of a thiol group and a carbon-carbon unsaturated bond.

8. The CMP polishing solution according to claim 6, wherein the anticorrosive agent includes at least one selected from the group consisting of 1,2,4-triazole, 4-amino-1,2,4-triazole, glycine, and 6-aminohexanoic acid.

9. The CMP polishing solution according to claim 1, wherein the CMP polishing solution is used for a base body including a first portion formed from an insulating material and a second portion provided on the first portion and formed from a tungsten material, to polish at least the second portion.

10. A stock solution that provides the polishing solution according to claim 1 by being diluted two-fold or more with an aqueous liquid medium.

11. A method for polishing a base body, the method comprising:
a step of preparing a base body including a first portion formed from an insulating material and a second portion provided on the first portion and formed from a tungsten material;
a step of disposing the base body on a polishing pad such that the polishing pad faces a surface of the second portion on the opposite side from the first portion; and
a step of supplying the polishing solution according to claim 1 between the polishing pad and the base body, while polishing at least the second portion by moving the polishing pad and the base body relative to each other.
